(19) United States
(12) Patent Application Publication
(10) Pub. No.: US 2026/0079789 A1
(43) Pub. Date: Mar. 19, 2026

(54) APPARATUSES, SYSTEMS, AND METHODS FOR BOUNDED FAULT COMPLIANT DATA PACKETS

(71) Applicant: Micron Technology, Inc., Boise, ID (US)

(72) Inventor: Sujeet Ayyapureddi, Boise, ID (US)

(21) Appl. No.: 19/282,921

(22) Filed: Jul. 28, 2025

Related U.S. Application Data
(60) Provisional application No. 63/695,716, filed on Sep. 17, 2024.

(51) Int. Cl. G06F 11/10; G11C 7/10

(52) U.S. Cl. CPC G06F 11/1044; G11C 7/10

(57) ABSTRACT

Apparatuses, systems, and methods for bounded fault compliance may include data packet definitions that cause metadata to be provided on a single DQ terminal in some examples. Metadata stored in different regions of a memory array are provided on different DQs in the data packet definition in some examples. The data packet definition may include empty or undefined portions in some examples. The data packet definition may cause the metadata to be output at a midpoint of a data burst in some examples.

### CROSS REFERENCE TO RELATED APPLICATION(S)

This application claims the benefit under 35 U.S.C. § 119 of the earlier filing date of U.S. Provisional Application Ser. No. 63/695,716 filed on Sep. 17, 2024 the entire contents of which is hereby incorporated by reference in its entirety for any purpose.

### BACKGROUND

This disclosure relates generally to semiconductor devices, and more specifically to semiconductor memory devices. In particular, the disclosure relates to memory, such as dynamic random access memory (DRAM). Information may be stored in memory cells, which may be organized into rows (word lines) and columns (bit lines) of an array. Various types of information may be stored in the array, such as data, error correction code (ECC) data, and metadata. The data may be information provided by an external device (e.g., controller, processor, host system). The ECC data may provide information that may be used to detect and/or correct errors in the data. The metadata may provide information about the data, ECC data, the memory device, and/or a device in communication with the memory device (e.g., a controller).

DRAM users are increasingly utilizing metadata to supplement the data stored in the memory array. For example, metadata may be used to store a “poison bit” that indicates that the data associated with the metadata is erroneous and should be discarded and/or replaced by an external device (e.g., controller, host, and/or system on a chip). In another example, metadata may store a pointer to a storage location that may allow the external device to determine what location in the array to access the next associated data. In some applications, this may be analogous to a head and/or tail of a linked list. These are merely examples, and other uses of metadata are also possible.

In many applications, multiple memory devices are used by a device and/or computing system. The memory devices may be packaged together in a memory module. For example, single in-line memory modules (SIMMs), dual in-line memory modules (DIMMS), small outline DIMMs (SODIMMs), and rambus in-line memory modules (RIMM) may include multiple memory devices. Memory modules may include circuitry to facilitate use of the multiple memory devices.

### BRIEF DESCRIPTION OF THE DRAWINGS

FIG. 1 is a block diagram of a memory system according to some embodiments of the present disclosure.

FIG. 2 is a block diagram of a semiconductor device according an embodiment of the disclosure.

FIG. 3 is a block diagram of a portion of a memory device according to some embodiments of the present disclosure.

FIG. 4 illustrates data packet definitions for different architectures according to some embodiments of the present disclosure.

FIG. 5 illustrates data packet definitions for different architectures according to some embodiments of the present disclosure.

FIG. 6 illustrates a data packet definition for a 2p3 architecture according to some embodiments of the present disclosure.

FIG. 7 is a flow chart of a method according to some embodiments of the present disclosure.

FIG. 8 illustrates data packet definitions for different architectures according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Semiconductor memory devices may store information in multiple memory cells. The information may be stored as a binary code, and each memory cell may store a single bit of information as either a logical high (e.g., a “1”) or a logical low (e.g., a “0”). The memory cells may be organized at the intersection of word lines (rows) and bit lines (columns) an array. The memory may further be organized into one or more memory banks. The banks may be organized into bank groups, where each bank group includes one or more banks. Each bank may include multiple of rows and columns. During operations, the memory device may receive a command and an address which specifies one or more rows and one or more columns and then execute the command on the memory cells at the intersection of the specified rows and columns (and/or along an entire row/column). The address may further specify the bank group and/or bank for execution of the command. In some applications, rows may be specified by 17-bit row addresses and columns may be specified by 12-bit column addresses. However, the number of bits used for the addresses may vary depending on the size and/or organization of the memory.

The columns may generally be organized into column planes, each of which includes a number of sets of individual columns all activated by a column select signal (CS) (e.g., column selects). Each bank may include some number X column planes. A column plane may receive some number N of column select (CS) signals, each of which may activate some number M of individual bit lines. As used herein, a column select set or CS set may generally refer to a set of bit lines which are activated by a given value of the CS signal within a column plane. The column select signal may be represented by (all or a portion of) a column address (CA). Responsive to a column select signal, data may be provided from corresponding locations from the column planes. The data from the column planes associated with the column select signal may be referred to as a cache line.

Memory devices may be packaged together onto a memory module. The memory module may include various circuits to facilitate use of the multiple memory devices. For example, the memory module may include circuitry for distributing signals to the memory devices. The memory module may include one or more error correction devices, which may store information (e.g., ECC data) used to correct errors when bits are read out from the memory devices (e.g., data and/or metadata). For example, each memory device may have a number of data input/output (or DQ) terminals. Each DQ terminal may send or receive a burst of serial bits from/to the associated memory device. The number of DQ terminals and/or the length of a burst (burst length) may be based on memory type and/or an operation mode of the memory device. Some memory module architectures may use the error correction devices to be able to correct up to one DQ terminal (or one set of DQ terminals) worth of bits. In other applications, error correction devices or other error correction devices may be included in a controller (e.g., a memory controller) or other device in communication with the memory module.

Typically, error correction devices can only correct and/or detect a certain number of errors in a section of bits. The number of errors that can be corrected and/or detected may be based, at least in part, on a number of bits to be corrected and a number of parity bits generated. There may be additional limits to the capabilities of error correction devices. For example, the error correction device may be limited to correcting errors in certain portions of the bits. Thus, there may be “fault lines” between the portions. An error that crosses a fault line may not be able to be corrected by the error correction device. For example, in DDR5, for a x8 device, either the upper nibble (e.g., DQ0-3) or lower nibble (e.g., DQ4-7) may have correctable errors. The error correction device may be capable of correcting errors from two DQs in a same nibble, but the error correction device may not be able to correct errors if the two DQs are in different nibbles. Thus, there may be a “fault line” between the nibbles. Accordingly, it is desirable to use techniques to prevent or reduce errors from “smearing” across fault lines to reduce the risk and/or frequency of uncorrectable errors. When errors are confined to either side of a fault line, may be referred to as a “bounded fault” implementation.

As noted above, information is provided to and from the DQ terminals as bursts of serial bits. In a read operation, the bits are accessed in parallel from the memory array. Individual bits are assigned to a DQ terminal as well as a place in the burst from the DQ by serializer circuits. For example, a bit may be assigned to DQ2 and the 12^{th} bit out of 32 bits transmitted from DQ2 during a burst. The DQ and order of the bit may be based on where in the memory array the bit was stored in some embodiments. During a write operation, the serialized bits are parallelized by de-serializer circuits and stored in the memory array. Where a bit is stored may be based on what DQ terminal and in what order it was received.

The mapping between the memory array and the DQs/bursts may be provided in a data packet definition. In some applications, the data packet definition may be provided in a specification of the memory device and/or memory module. In some applications, the data packet definition may be provided in a standard (e.g., JEDEC, IEEE). Even if information is stored within the memory array in a manner that allows the memory array to be bounded fault-compliant for internal error correction purposes (e.g., internal ECC circuit), if the data packet definition maps information from areas of the memory array to different DQs, it could cause the output of the memory device to have errors that cross fault lines of the external error correction device. This may prevent error correction devices in memory modules and/or controllers from being able to correct errors in the information provided by the memory device.

According to embodiments of the present disclosure, a data packet may be defined such that data and/or metadata stored in a portion of a memory array are mapped to DQ terminals such that the data and/or metadata provided is bounded fault-compliant from the perspective of an external error correction device. For example, information stored in a column plane and/or information associated with a sub-word line driver may be provided to a single DQ instead of multiple DQs or to two DQs on a same side of a fault line. Accordingly, a fault may only corrupt information along one DQ terminal and/or nibble, which may make the error ‘bounded fault’ compliant, as the fault does not exceeds the boundary (e.g., 1 DQ or set of DQs) of what the error correction device can correct. In other words, the error does not cross the fault line.

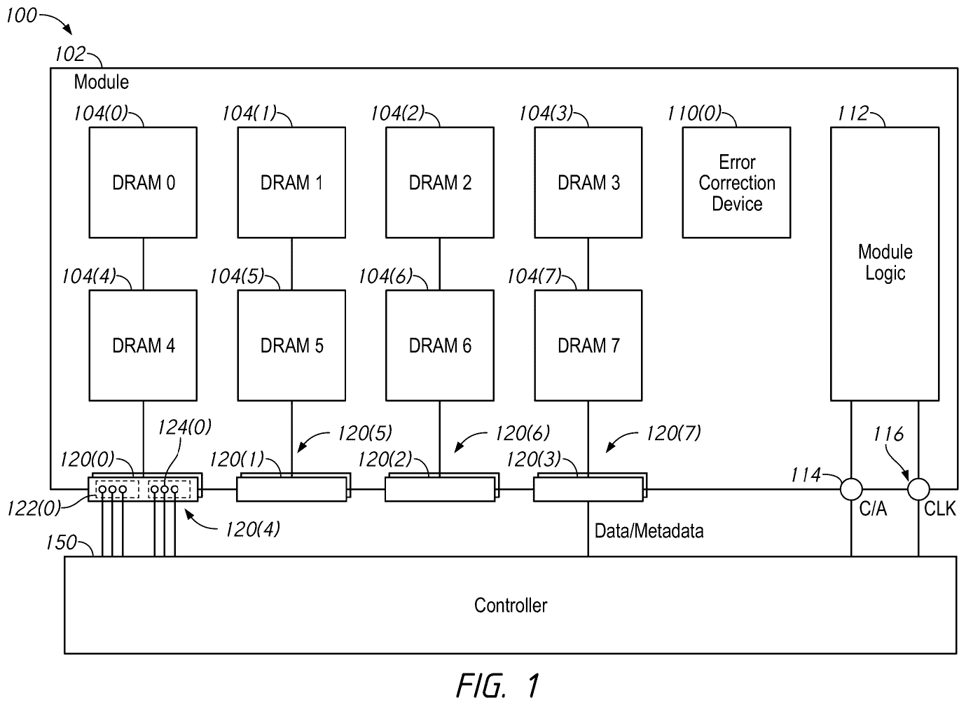

FIG. 1 is a block diagram of a memory system according to some embodiments of the present disclosure. The memory system 100 includes a memory module 102 and a controller 150 which operates the memory module 102. The module includes a number of memory devices 104(0-7). The memory devices 104 may be used to store information (e.g., metadata, data, etc.). In the example shown in FIG. 1, there are eight memory devices, but in other embodiments, there may be more or fewer memory devices (e.g., 4 devices, 16 devices). In some embodiments, additional memory devices 104 may be included to provide for redundancy. In some embodiments, memory module 102 may be a dual in-line memory module (DIMM). In some embodiments, what is shown in FIG. 1 may represent only half of the DIMM (e.g., one of the two channels). In other words, memory module 102 may include sixteen memory devices 104. In some embodiments, memory devices 104 may be x3, x4, x6, or x8 memory devices. That is, either three, four, six, or eight DQ terminals (e.g., pins) may be active. In some embodiments, the memory devices 104 may support multiple operation modes (e.g., x3 and x6, x4 and x8). In some embodiments, whether the memory devices 104 operate in a particular xN mode may be based, at least in part, on values stored in mode registers (not shown in FIG. 1) of the memory devices 104. In some embodiments, the memory devices 104 may be x12, x16, x24, or x32 memory devices.

The memory module 102 includes an error correction device 110 is used to correct errors in information read from the data memory devices 104. In the example shown in FIG. 1, module logic 112 receives commands and addresses over a command/address C/A bus from the controller 150 through a C/A terminal 114 and distributes those commands and addresses to the memory devices 104 and/or error correction device 110 over internal command and address buses (not shown). The module logic 112 receives clock signals from the controller 150 through a CLK terminal 116. Clock signals may include system clock signals and/or data clock signals. The module logic 112 may distribute the clock signals to the memory devices 104 and/or error correction device 110 over internal clock buses (not shown).

Information is communicated between the controller 150 and the module 102 along data buses which couple to data terminals (DQ) terminals 124 of the module 102. The data terminals 124 are organized into pseudo-channels 122 and channels 120. Each channel is a set of data terminals 124 associated with a memory device 104. In some embodiments, the number of DQ terminals 124 associated with a memory device 104 may be the same as the number of DQ terminals of the memory device 104. That is, there may be a 1:1 correspondence between the DQ terminals 124 and the DQ terminals of the memory device 104 in some embodiments.

Each channel 120(0) to 120(7) includes one or more pseudo-channels 122, which may be operated independently of each other. In some embodiments, each pseudo-channel 122 may operate in a substantially same manner. In some embodiments, the pseudo-channels 122 may be operated concurrently or one of the two pseudo-channels 122 may be used at a time. In the example embodiment shown in FIG. 1, each channel 120 includes two pseudo-channels 122, each of which includes three data terminals 124 (2p3 architecture). Since the memory devices and channels may generally be similar to each other, only a single device 104(0) and its associate channel 120(0) are described in detail herein. In order to simplify the layout of the figure, an arrangement of two rows of four devices 104 each is shown, and their associated channels 120 are shown as stacked boxes. However, the representation of FIG. 1 does not necessarily represent the layout of a physical device. For example, a single row of 8 devices 104 may be used. Similarly, various buses and signal lines have been simplified down to a single line for clarity on the drawing, however, multiple physical signal lines may be represented by a single line in the drawing.

During an example write operation for 2p3 architecture, the controller 150 provides a write command and addresses (e.g., row, column, and/or bank addresses as explained in more detail herein) over the C/A terminal 114 to the module 102. The module logic 112 distributes the command and address to the memory devices 104(0) to 104(7). The controller 150 also provides information to be written along the various DQ channels 120(0) to 120(7). Since the pseudo-channels 122 may be operated independently, a single pseudo-channel 122 and its three DQ terminals 124 will be considered. Each data terminal receives a serial burst of bits, which together represent a codeword of information. For example, each terminal receives 24 bits in series, for a total of 72 bits. In some embodiments, the 72 bits may include 64 bits of data and 8 bits of metadata. In some embodiments, the data packet may be defined such that the data is provided on all three of the DQ terminals 124 of the pseudo-channel 122, and the metadata is provided on one of the DQ terminals 124 of the pseudo-channel 122.

During an example read operation for 2p3, the controller 150 provides a read command and addresses along the C/A terminal 114. The module logic 112 distributes these to the memory devices 104 to 110 and data and metadata is read out from the locations specified by the addresses. Each DQ terminal 124 provides 24 bits of read information, for a total of 72 bits per memory device 104. In some embodiments, the data packet is defined such that all of the DQ terminals 124 of a pseudo-channel 122 provide data bits, and one of the DQ terminals of the pseudo-channel 122 may provide metadata bits.

During write operations, the error correction device 110 may generate and store error correction information (e.g., parity bits) based on the information provided to the channels 120 in some embodiments. Additionally or alternatively, the error correction device 110 may receive and store error correction information from the controller 150 through a channel (not shown). During read operations, the error correction device 110 may correct errors in the information provided from the memory devices 104 based on the error correction information. Alternatively, the error correction device 110 may provide the error correction information to the controller 150 through a channel, and the controller 150 may perform error correction based, at least in part, on the information provided by the error correction device 110.

In some embodiments, the read and write operations may use a single-access pass to store both the data along with the metadata bits. In some embodiments, ECC data generated by the memory device 104 based on the data and metadata may also be stored in the pass. Accordingly, the data, metadata, and ECC data may all be accessed as a single access pass.

According to embodiments of the present disclosure, providing metadata from one DQ terminal in a pseudo-channel 122 in a 2p3 architecture may prevent or reduce errors in metadata from crossing a fault line for error correction by the error correction device 110 and/or controller 150. If there are errors in the metadata, it will only impact one of the DQ terminals 124, and the error correction device 110 may be capable of correcting the error. According to embodiments of the present disclosure, in other architectures, such as 2p6 and 2p8, 8 bits of metadata may be provided to one DQ terminal 124 of an upper nibble or a lower nibble of a pseudo-channel 122. This may provide a bounded fault-compliant data packet definition.

In some embodiments, 8 bits of additional metadata may be provided during a burst for a total of 16 bits of metadata. In some embodiments, the two bytes of metadata may be stored in different locations of the memory device 104 (e.g., different column planes). In these embodiments, one byte of metadata may be provided on a DQ of an upper nibble and the other byte of metadata may be provided on a DQ of a lower nibble. This may provide a bounded fault-compliant data packet definition for additional metadata.

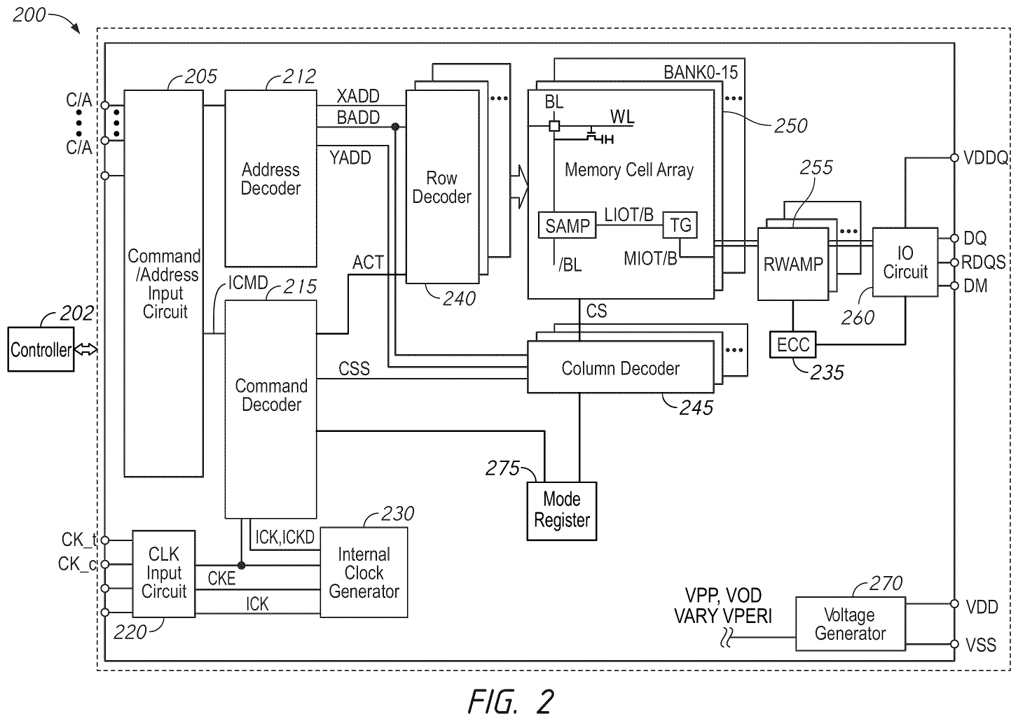

FIG. 2 is a block diagram of a semiconductor device according to some embodiments of the present disclosure. The apparatus may be a semiconductor device 200, and will be referred to as such. In some embodiments, the semiconductor device 200 may include, without limitation, a dynamic random access (DRAM) device integrated into a single semiconductor chip. In some examples, the DRAM may be a double data rate (DDR) memory. In some embodiments, one or all of the memory devices 104(0-7) of FIG. 1 may include semiconductor device 200.

The semiconductor device 200 includes a memory die. The die may be mounted on an external substrate, for example, a memory module substrate, a mother board or the like (e.g., package-on-package (PoP)). The semiconductor device 200 may include a memory array 250. The memory array 250 includes a plurality of banks BANK0-15, each bank including a plurality of word lines WL, a plurality of bit lines BL, and a plurality of memory cells MC arranged at intersections of the plurality of word lines WL and the plurality of bit lines BL. Although sixteen banks are shown in FIG. 2, memory array 250 may include any number of banks.

The selection of the word line WL is performed by a row decoder 240 and the selection of the bit line BL is performed by a column decoder 245. Sense amplifiers (SAMP) are located for their corresponding bit lines BL and connected to at least one respective local I/O line pair (LIOT/B), which is in turn coupled to at least respective one main I/O line pair (MIOT/B), via transfer gates (TG), which function as switches. The TG may be coupled to one or more read/write amplifiers (RWAMP) 255, which may be coupled to an error correction code (ECC) circuit 235. The ECC circuit 235 may be coupled to an IO circuit 260, which may be coupled to one or more external terminals of semiconductor device 200, such as the DQ terminals.

Read data (e.g., data and/or metadata) from the bit line BL is amplified by the sense amplifier SAMP and transferred to read/write amplifiers 255 over complementary local data lines (LIOT/B), transfer gate (TG), and complementary main data lines (MIOT/B) to the ECC circuit 235. The ECC circuit 235 provides corrected (if needed) data to the IO circuit 260. The IO circuit 260 may include serializer circuits that organize the read data into multiple series of bits to be provided to the DQ terminals. For example, if four DQ terminals are active, the IO circuit 260 may organize the read data into four serial bursts of bits, one for each DQ terminal. According to embodiments of the present disclosure, the arrangement of bits may be based on a data packet definition. The IO circuit 260 may have hardwired or programmable circuits configured to provide the bits based on the data packet definition.

Conversely, write data (e.g., data and/or metadata) provided at the DQ terminals (e.g., by controller 202) may be deserialized by the IO circuit 260 based on the data packet definition and provided to the ECC circuit 235. The write data is outputted from the ECC circuit 235 and is transferred to the sense amplifier SAMP over the complementary main data lines MIOT/B, the transfer gate TG, and the complementary local data lines LIOT/B, and written in the memory cell MC coupled to the bit line BL.

The semiconductor device 200 may employ a plurality of external terminals that include command and address terminals coupled to a command/address (C/A) bus to receive command and address signals, clock terminals to receive clock signals CK_t and CK_c, data terminals DQ, RDQS, and power supply terminals VDD, VSS, VDDQ, and VSSQ.

The C/A terminals may be supplied with an address and a bank address signal from outside, for example, from a controller 202. The address signal and the bank address signal supplied to the address terminals are transferred, via a command/address input circuit 205, to an address decoder 212. The address decoder 212 receives the address signals and supplies a decoded row address signal XADD to the row decoder 240, and a decoded column address signal YADD to the column decoder 245. The address decoder 212 also receives the bank address signal BADD and supplies the bank address signal to the row decoder 240 and the column decoder 245.

The C/A terminals may further be supplied with command signals from, for example, a controller 202. In some embodiments, controller 202 may be implemented or included in controller 150. The command signals may be provided as internal command signals ICMD to a command decoder 215 via the command/address input circuit 205. The command decoder 215 includes circuits to decode the internal command signals ICMD to generate various internal signals and commands for performing operations, for example, a row activation signal (ACT) to select a word line. Another example may be providing internal signals to enable circuits for performing operations, such as control signals to enable signal input buffers that receive clock signals.

Each bank BANK0-15 may be organized into multiple physical column planes (CP). Each column plane may be associated with multiple column selects (e.g., CS0-63, CS0-59, CS0-55). In some embodiments, different column planes may be used to store different types of information. For example, some column planes may store data and another plane stores ECC data. The array 250 can be selectively configured to utilize one or more column planes to store metadata, for example, as described in U.S. Provisional Patent Application Nos. 63/695,446, 63/695,458, 63/695,465, 63/695,472, 63/695,482, and 63/695,495 filed Sep. 17, 2024, which are incorporated herein by reference for any purpose. However, other techniques may be used to store the data, metadata, and/or ECC data in the array 250 without departing from the principles of the present disclosure. Optionally, a further plane may store GCR data.

The C/A terminals may receive an access command which is a read command. When a read command is received, and a bank address, a row address and a column address are timely supplied with the read command, a codeword including read data, metadata, and read ECC data (e.g., parity bits) is read from memory cells in the memory array 250 corresponding to the row address and column address. The read command is received by the command decoder 215, which provides internal commands so that read data from the memory array 250 is provided to the ECC circuit 235. The ECC circuit 235 may use the parity bits in the codeword to determine if the codeword includes any errors, and if any errors are detected, may correct them to generate a corrected codeword (e.g., by changing a state of the identified bit(s) which are in error). The corrected codeword (without the parity bits) is output from the data terminals DQ via the input/output circuit 260.

The C/A terminals may receive an access command which is a write command. When the write command is received, and a bank address, a row address, and a column address are timely supplied as part of the write operation, and write data is supplied through the DQ terminals to the ECC circuit 235. The write data (which may include write data and metadata) supplied to the data terminals DQ is written to a memory cells in the memory array 250 corresponding to the row address and column address. The write command is received by the command decoder 215, which provides internal commands so that the write data is received by data receivers in the input/output circuit 260. The write data is supplied via the input/output circuit 260 to the ECC circuit 235. The ECC circuit 235may generate ECC data (e.g., a number of parity bits) based on the write data, and the write data and the parity bits may be provided as a codeword to the memory array 250 to be written into the memory cells MC.

The ECC circuit 235 may be used to ensure the fidelity of the data read from a particular group of memory cells to the data written to that group of memory cells. The semiconductor device 200 may include a number of different ECC circuits 235, each of which is responsible for a different portion of the memory cells MC of the memory array 250. For example, there may be one or more ECC circuits 235 for each bank of the memory array 250. Typically, each bank BANK0-15 includes a column plane for the storage of ECC data (e.g., parity bits) and additional column planes for the storage of data and metadata. In these applications, the ECC circuit 235 generates eight bits of ECC data (e.g., 8 bits of ECC data) for each cache line. This may allow for the ECC circuit 235 to provide single bit error correction in some embodiments. More or fewer bits of ECC data may be generated in other embodiments, and more or fewer errors may be capable of being corrected.

The command decoder 215 may access mode register 275 that is programmed with information for setting various modes and features of operation for the semiconductor device 200. For example, the mode register 275 may provide parameters that allow the semiconductor device 200 to operate at different frequencies, provide different burst lengths (e.g., 16, 24, 32), allow banks BANK0-15 to be organized into different groups, operate in xN mode (where N is a whole number greater than 0), whether or not metadata is stored, and/or other different operating conditions. In some embodiments, mode register 275 may include multiple registers.

The information in the mode register 275 may be programmed by providing the semiconductor device 200 a mode register write command, which causes the semiconductor device 200 to perform a mode register write operation. In some embodiments, data to be written to the mode register 275 is provided via the C/A terminals and/or the DQ terminals. The command decoder 215 accesses the mode register 275, and based on the programmed information along with the internal command signals provides the internal signals to control the circuits of the semiconductor device 200 accordingly. Information programmed in the mode register 275 may be externally provided by the semiconductor device 200 using a mode register read command, which causes the semiconductor device 200 to access the mode register 275 and provide the programmed information (e.g., to the memory controller 202). In some embodiments, the information may be provided via the C/A terminals and/or the DQ terminals.

Turning to the explanation of the external terminals included in the semiconductor device 200, the clock terminals and data clock terminals are supplied with external clock signals and complementary external clock signals. The external clock signals CK_t, CK_c may be supplied to a clock input circuit 220. When enabled, input buffers included in the clock input circuit 220 pass the external clock signals. For example, an input buffer passes the CK_t and CK_c signals when enabled by a CKE signal from the command decoder 215. The clock input circuit 220 may use the external clock signals passed by the enabled input buffers to generate internal clock signal ICK. The internal clock signal ICK are supplied to internal clock circuit 230 for providing one or more clock signals to the various components of semiconductor device 200.

The internal clock circuits 230 includes circuits that provide various phase and frequency controlled internal clock signals based on the received internal clock signals. For example, the internal clock circuits 230 may include a clock path (not shown in FIG. 2) that receives the ICK clock signal and provides internal clock signals ICK and ICKD to the command decoder 215. Optionally, the input/output circuit 260 may include clock circuits and driver circuits for generating and providing the RDQS signal to a controller.

The power supply terminals are supplied with power supply potentials VDD and VSS. These power supply potentials VDD and VSS are supplied to an internal voltage generator circuit 270. The internal voltage generator circuit 270 generates various internal potentials VPP, VOD, VARY, VPERI, and the like and a reference potential ZQVREF based on the power supply potentials VDD and VSS. The internal potential VPP is mainly used in the row decoder 240, the internal potentials VOD and VARY are mainly used in the sense amplifiers included in the memory array 250, and the internal potential VPERI is used in many other circuit blocks.

The power supply terminal is also supplied with power supply potential VDDQ. The power supply potentials VDDQ is supplied to the input/output circuit 260 together with the power supply potential VSS. The power supply potential VDDQ may be the same potential as the power supply potential VDD in an embodiment of the disclosure. The power supply potential VDDQ may be a different potential from the power supply potential VDD in another embodiment of the disclosure. However, the dedicated power supply potential VDDQ is used for the input/output circuit 260 so that power supply noise generated by the input/output circuit 260 does not propagate to the other circuit blocks.

While in FIG. 2, controller 202 is shown interacting directly with semiconductor device 200, when semiconductor device 200 is included in a memory module, such as memory module 102, various external terminals may receive signals and power via the memory module, such as via module logic 112 and/or DQ channels 120.

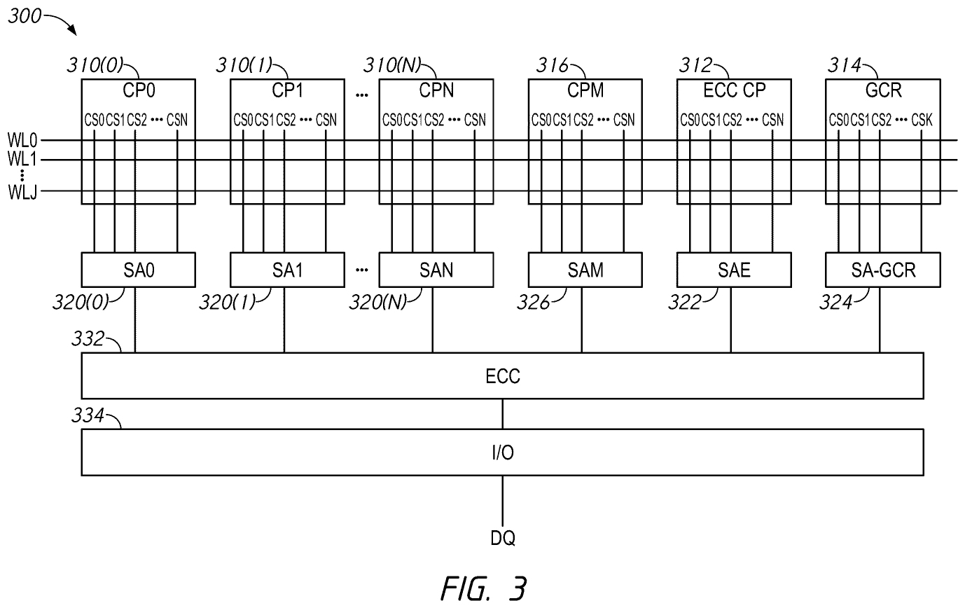

FIG. 3 is a block diagram of a portion of a memory device according to some embodiments of the present disclosure. The memory device 300 may, in some embodiments, represent a portion of the semiconductor device 200 of FIG. 2 or a portion of one or more of the memory devices 104 in FIG. 1. FIG. 3 shows a portion of a memory array 310-316 and 320-326 which may be part of a memory bank (e.g., BANK0-15 of FIG. 2) along with selected circuits used in the data path such as the ECC circuit 332 (e.g., 235 of FIG. 2) and IO circuits 334 (e.g., 260 of FIG. 2). For clarity certain circuits and signals have been omitted from the view of FIG. 3.

The memory device 300 is organized into a number of column planes 310-316. Each of the column planes represents a portion of a memory bank. Each column plane 310-316 includes a number of memory cells at the intersection of word lines WL and bit lines. The bit lines may be grouped together into sets which are activated by a value of a column select (CS) signal. For the sake of clarity, only a single vertical line is used to represent the bit lines of each column select set, however, there may be multiple columns accessed by that value of CS. For example, each line may represent eight bit lines, all accessed in common by a value of CS. As used herein, a ‘value’ of CS may refer to a decoded signal provided to sets of bit lines (e.g., from a column decoder such as 245 in FIG. 2). A first value may represent a first value of a multibit CS signal, or after decoding a signal line associated with that value being active. The word lines may be extended across multiple of the column planes 310-316.

In the example shown in FIG. 3, the memory device 300 includes a set of column planes 310 that store data and at least one column plane 316 that stores metadata. In other examples, portions of column planes 310 may include metadata while other portions of the column plane store data. In the example shown, memory device 300 includes an ECC column plane 312 to store ECC information, such as error correction parity bits, which may be referred to as ECC data. However, in other examples, portions of column planes 310 may be configured to store ECC data along with data and/or metadata. The example arrangement of information (data, metadata, and ECC data) in memory device 300 is provided is merely illustrative, and other arrangements of information in the memory array may be used.

In some embodiments, the memory device 300 may also include an optional global column redundancy (GCR) column plane 314. In some embodiments, the GCR column plane 314 may have fewer memory cells (e.g., fewer column select groups) than the data column planes 310. The GCR CP 314 includes a number of redundant columns which may be used as part of a repair operation. If a value of the CS signal is identified as including defective memory cells in one of the data column planes 310, then the memory may be remapped such that the data which would have been stored in that column plane for that value of CS is instead stored in the GCR CP 314.

In an example, the memory device 300 may include 16 data column planes 310(0)-310(15) and one metadata column plane 316. Each set of column select includes 8 bit lines. When a word line is opened responsive to a row address, and a column select signal is provided to each of the 17 column planes then 8 bits are accessed from each of the 17 column planes for a total of 136 bits (128 data bits and 8 metadata bits). A column select signal is also provided to the ECC column plane 312, although that column select signal may be a different value than the one provided to the column planes 310 for an additional 8 bits. If a repair has been performed, the GCR CP 314 may also be accessed and the value on a GCR LIO may be used while ignoring the LIO of the column plane it is replacing. As part of an access pass, 128 bits from the data column planes 310 (with 8 bits substituted from the GCR CP 314 if there has been a repair) and 8 bits from the metadata plane 316 along with 8 additional bits from the ECC CP 312 are retrieved. A total of 136 bits of data and metadata may be provided to a controller (e.g., controller 150 and/or 202).

In another example, the memory device 300 may include 16 data column planes 310(0)-310(15) and two metadata column planes 316. When a word line is opened responsive to a row address, and a column select signal is provided to each of the 18 column planes then 8 bits are accessed from each of the 18 column planes for a total of 144 bits (128 data bits and 16 metadata bits). A column select signal is also provided to the ECC column plane 312, although that column select signal may be a different value than the one provided to the column planes 310 for an additional 8 bits. If a repair has been performed, the GCR CP 314 may also be accessed and the value on a GCR LIO may be used while ignoring the LIO of the column plane it is replacing. As part of an access pass, 128 bits from the data column planes 310 (with 8 bits substituted from the GCR CP 314 if there has been a repair) along with 16 bits from the metadata column planes 316 and 8 additional bits from the ECC CP 312. A total of 1144 bits of data and metadata may be provided to a controller (e.g., controller 150 and/or 202).

During read operations, data may be provided from the column planes 310 to the sense amplifiers 320 to the ECC circuit 332. Metadata may be provided from column plane(s) 316 to sense amplifier(s) 326 and ECC data may be provided from column plane 312 to sense amplifier 322 to the ECC circuit 332. (If a repair has been made, data may also be provided from column plane 314 to sense amplifier 324 to the ECC circuit 332.) The ECC circuit 332 may use the ECC data provided from column plane 312 to correct and/or detect errors in the data and/or metadata. The ECC circuit 332 may output the data and metadata (corrected, if needed) to the I/O circuit 334. The I/O circuit 334 may provide the data and metadata to the DQ based on a data packet definition. The DQ may make the data and metadata to an external device (e.g., a controller such as 150 in FIGS. 1 and/or 202 in FIG. 2). In some embodiments, the DQ of memory device 300 may be coupled to DQ of a memory module, such as DQ 124. Optionally, the ECC circuit 332 may further provide error information for output on the DQ.

During write operations, data and metadata may be received by the I/O circuit 334 from the DQ and provide the data and metadata to the ECC circuit 332. Optionally, error information may also be received and provided to the ECC circuit 332. The ECC circuit 332 may generate parity bits and/or other error correction information for the data and metadata. The ECC circuit 332 may provide the data to sense amplifiers 320 for storage in column planes 310. Metadata may be provided to sense amplifier(s) 326 for storage in column plane(s) 316 and the error correction information may be provided to sense amplifier 322 for storage in column plane 312. (If a repair has been made, data may also be provided from the ECC circuit 332 to sense amplifier 324 for storage in column plane 314.) Where the data and metadata are stored may be based on what DQ terminal the data or metadata bit was received at and the order in which it was received at the DQ terminal based on the data packet definition.

Data, metadata, ECC data, and other information may be stored in the memory array of a memory device in a variety of arrangements, including the arrangement described with reference to FIG. 3. In some embodiments, the information may be stored in a bounded fault-compliant manner with respect to the ECC circuit of the memory device, such as ECC circuit 332 and/or ECC circuit 235. For example, information stored in a column plane may be provided to a sub-word line driver (not shown) such that a defect in the column plane is not spread across multiple sub-word line drivers. This may reduce the risk of an error crossing a fault line of the memory array and causing an error that is not correctable by the ECC circuit 332 of the memory device 300.

The ECC circuit 332 may not always be able to correct all of the errors in the data. Even if the ECC circuit 332 is able to successfully correct errors in the information from the memory array, additional errors may be introduced by faults in other components. For example, a portion of the I/O circuit 334 may have a defect or a DQ of the memory device 300 or a memory module including the memory device 300 may have a defect. These defects in other components may hinder transmission of the information, introducing errors in the data. Error correction devices (error correction device 110) external to the memory devices may be used to correct errors in the information transmitted from the memory devices.

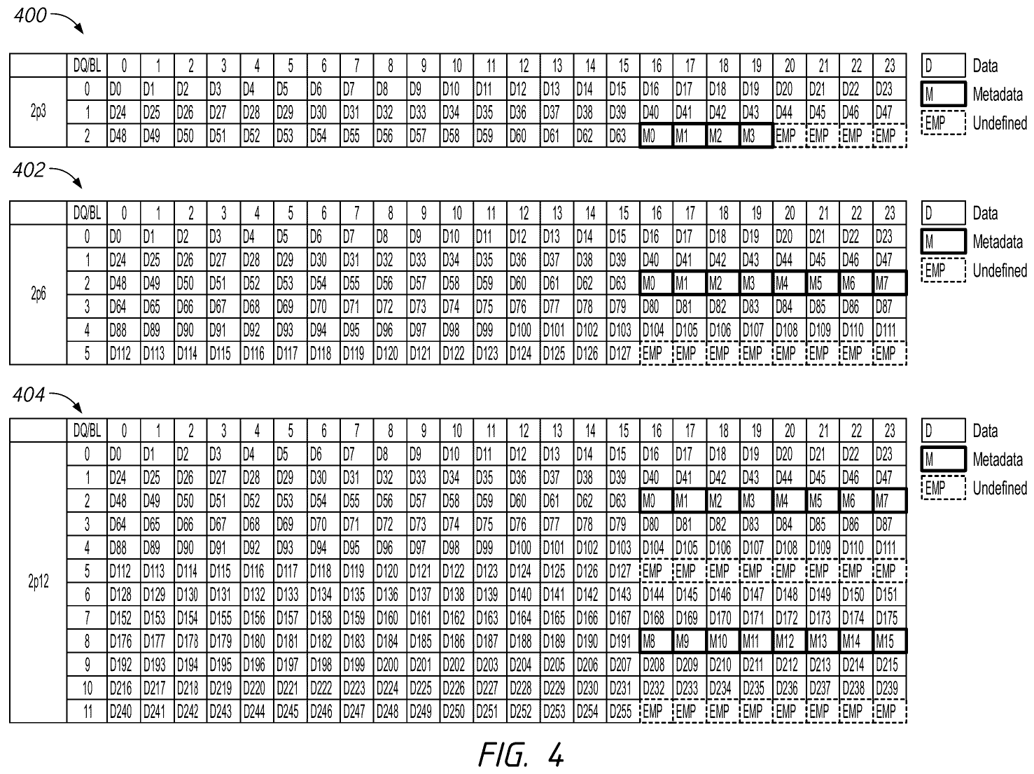

According to embodiments of the present disclosure, the I/O circuit 334 may arrange the data and metadata bits from the ECC circuit 332 into a data packet that is bounded fault-compliant from the perspective of the error correction devices. FIGS. 4-6 provide examples of data packet definitions that may prevent errors from crossing fault lines of error correction devices. Further, the data packet definitions provided in FIGS. 4-6 may accommodate non-binary numbers of DQ terminals. The data packet definitions disclosed herein may reduce the risk of uncorrectable errors and/or provide bounded fault-compliant implementations of data packets.

For each table in FIGS. 4-6, the first column indicates a DQ terminal, and the top row indicates a bit in a series of bits in a burst length (BL). Further, D#indicate bits of data, M#indicate bits of metadata, and EMP indicates undefined bits. In some applications, EMP bits may not be provided, ignored, or discarded. In some applications, EMP bits may be additional bits of information for an application-specific purpose. For example, in some embodiments, the EMP bits may be used as cyclical redundancy check (CRC) bits. In some applications, EMP bits may be additional metadata bits. When the EMP bits are used as additional metadata bits, they may be stored in a different location of a memory device and/or memory module than the defined metadata bits (e.g., different column plane, different bank, etc.) in some embodiments.

FIG. 4 illustrates data packet definitions for different architectures according to some embodiments of the present disclosure. The data packet definitions shown in FIG. 4 may be implemented by a memory device, such as one or all of memory devices 104, semiconductor device 200, and/or memory device 300 in some embodiments. The data packet definitions may also be implemented by a controller such as controller 150 and/or controller 202.

Table 400 illustrates a data packet definition for a 2p3 architecture where a channel (e.g., channel 120) is divided into two pseudo-channels that each include three DQ terminals (e.g., DQ 124). In the 2p3 architecture, in some embodiments, one pseudo-channel may provide one nibble and the other pseudo-channel may provide another nibble. In some embodiments, information provided on both pseudo-channels may be provided by a same memory device. In other embodiments, information may be provided from different memory devices. Because each pseudo-channel (e.g., pseudo-channels 122) may operate independently, the data packet definition for only one pseudo-channel is shown in table 400. The data packet defined in table 400 has a burst length of 24 bits (0-23). DQ0 receives 24 bits of data (D0-23) and DQ1 also receives 24 bits of data (D24-47). DQ2 receives 16 bits of data (D48-63). Thus, the data packet includes 64 bits of data. When a memory device including the pseudo-channel has metadata storage enabled, DQ2 receives four bits of metadata (M0-3) and the remaining bits of the burst (BL20-23) are undefined (EMP). Thus, in total, during a burst, the pseudo-channel may provide 68 bits (64 data bits+4 metadata bits), and the undefined bits may or may not be provided. In some embodiments, the undefined bits may be replaced with four additional metadata bits and the pseudo-channel may provide 72 bits (64 data bits+8 metadata bits). In some embodiments, the undefined bits may be replaced with CRC bits or other bits.

In some embodiments, the data D0-7, D8-15, D16-23, D24-31, and so on, may each be associated with different column planes. When a column select is associated with eight bits, because the burst length is a multiple of eight (3×8=24), data from a column plane is provided to one DQ terminal. Thus, a defect in a column plane may not be “smeared” across multiple DQ. In some embodiments, the data associated with a sub-word line driver is provided to one DQ (e.g.,. D0-23 are associated with SWD0 and D24-47 are associated with SWD1). This may prevent a defect in a sub-word driver from being spread across multiple DQ. Internally, the metadata may be associated with one column plane and/or one sub-word line driver. The metadata is provided on one DQ such that errors in the metadata are not spread across multiple DQ. In some applications, this may provide for a bounded fault-compliant data packet definition.

Table 402 illustrates a data packet definition for a 2p6 architecture where a channel is divided into two pseudo-channels that each include six DQ terminals. In some embodiments, information provided on both pseudo-channels may be provided by a same memory device. In other embodiments, information may be provided from different memory devices. Because each pseudo-channel may operate independently, the data packet definition for only one pseudo-channel is shown in table 402. The data packet defined in table 402 has a burst length of 24 bits (0-23). DQ0 receives 24 bits of data (D0-23) and DQ1 also receives 24 bits of data (D24-47). DQ2 receives 16 bits of data (D48-63). When a memory device including the pseudo-channel has metadata storage enabled, DQ2 receives eight bits of metadata (M0-7). DQ3 and DQ4 each receive 24 bits of data, D64-87 and D88-111, respectively. DQ5 receives 16 bits of data (D112-D127) and is further assigned 8 undefined bits. Thus, in total, during a burst, the pseudo-channel may provide 136 bits (128 data bits+8 metadata bits), and the undefined bits may or may not be provided. In some embodiments, the undefined bits may be replaced with 8 additional metadata bits. In these embodiments, during a burst, the pseudo-channel may provide 144 bits (128 data bits+16 metadata bits). In some embodiments, the undefined bits may be used as CRC bits.

In some embodiments, the data D0-7, D8-15, D16-23, D24-31, and so on, may each be associated with different column planes. When a column select is associated with eight bits, because the burst length is a multiple of eight (3×8=24), data from a column plane is provided to one DQ terminal. Thus, a defect in a column plane may not be “smeared” across multiple DQ. In some embodiments, the data associated with a sub-word line driver is provided to one DQ (e.g.,. D0-23 are associated with SWD0 and D24-47 are associated with SWD1). This may prevent a defect in a sub-word driver from being spread across multiple DQ. Further, the data may be provided to the DQ terminals such that defects in the memory do not cross between the upper and lower “nibble” of the pseudo-channel. While a nibble typically refers to 4 bits, because the pseudo-channel has 6 DQ terminals, a nibble for the 2p6 architecture is three DQ terminals. For example, DQ0-2 are a lower nibble and DQ3-5 are an upper nibble.

Internally, the metadata may be associated with one column plane and/or one sub-word line driver. The metadata is provided on one DQ such that errors in the metadata are not spread across multiple DQ. Further, the metadata is provided symmetrically in the “middle” of the data packet between D0-D63 and D64-127. This provides separation of the data between the upper and lower nibbles on the DQ terminals. This may provide further prevent errors due to defects in areas of the memory array storing data from passing fault lines in some applications.

The undefined bits are also provided on one DQ. When the undefined bits are assigned additional metadata bits, these metadata bits may be stored in a different location in the memory device or module that includes the pseudo-channel. Even though the undefined bits are provided on a different DQ, because the bits are stored in a different location, it is unlikely that a fault affecting the metadata on DQ2 would be related to a fault affecting DQ5. A defect in the metadata on one DQ would not smear onto the other DQ. Accordingly, the data packet definition in table 402 may provide for a bounded fault-compliant data packet definition.

Table 404 illustrates a data packet definition for a 2p12 architecture where a channel is divided into two pseudo-channels that each include twelve DQ terminals. In some embodiments, information provided on both pseudo-channels may be provided by a same memory device. In other embodiments, information may be provided from different memory devices. Because each pseudo-channel may operate independently, the data packet definition for only one pseudo-channel is shown in table 404. The data packet defined in table 404 has a burst length of 24 bits (0-23). DQ0 receives 24 bits of data (D0-23) and DQ1 also receives 24 bits of data (D24-47). DQ2 receives 16 bits of data (D48-63). When a memory device including the pseudo-channel has metadata storage enabled, DQ2 receives eight bits of metadata (M0-7). DQ3 and DQ4 each receive 24 bits of data, D64-87 and D88-111, respectively. DQ5 receives 16 bits of data (D112-D127) and is further assigned 8 undefined bits. DQ6 and DQ7 each receive 24 bits of data, D128-151 and D152-175, respectively. DQ8 receives 16 bits of data (D176-191). When a memory device including the pseudo-channel has metadata storage enabled, DQ8 receives eight bits of metadata (M8-15). DQ9 and DQ10 each receive 24 bits of data, D192-215 and D216-239, respectively. DQ11 receives 16 bits of data (D240-D255) and is further assigned 8 undefined bits. In some embodiments, the undefined bits may be used as CRC bits.

In total, during a burst, the pseudo-channel may provide 272 bits (256 data bits+16 metadata bits), and the undefined bits may or may not be provided. In some embodiments, the undefined bits may be replaced with additional metadata bits. In these embodiments, during a burst, the pseudo-channel may provide 288 bits (256 data bits+32 metadata bits).

As discussed with reference to tables 400 and 402, in some embodiments, data and metadata from a column plane is provided to one DQ terminal. Thus, a defect in a column plane may not be “smeared” across multiple DQ. In some embodiments, the data associated with a sub-word line driver is provided to one DQ (e.g., D0-23 are associated with SWD0 and D24-47 are associated with SWD1). This may prevent a defect in a sub-word driver from being spread across multiple DQ. Further, the data may be provided to the DQ terminals such that defects in the memory do not cross between nibbles of the pseudo-channel.

Internally, metadata M0-7 may be associated with one column plane and/or one sub-word line driver and provided to one DQ such that errors in the metadata M0-7 are not spread across multiple DQ. Similarly, metadata M8-15 may be associated with one column plane and/or one sub-word line driver, which are different than the column plane and/or sub-word line driver associated with metadata M0-7. Because M8-15 are stored in a different location, errors in this byte of metadata is unlikely to be related to errors in M0-7. Accordingly, errors in the metadata are not spread across DQ terminals.

The two bytes of undefined bits are provided on different DQs. When the undefined bits are assigned additional metadata bits, these metadata bits may be stored in different locations in the memory device or module that includes the pseudo-channel, not only from each other, but also from M0-7 and M8-15. Thus, even though the undefined bits are provided on a different DQ, because the bits are stored in different locations, it is unlikely that a fault affecting the metadata on DQ5, DQ11, DQ2, or DQ8 would be related to a fault affecting one of the other DQ terminals associated with other bytes of metadata. Thus, defect in the metadata on one DQ would not smear onto the other DQ.

Further, the metadata M0-7 is provided in a middle of a first portion of the data D0-63 and D64-127, and M8-15 is provided in a middle of a second portion of the data D128-191 and D192-255. A first portion of the undefined bits is placed between data bit D127 and D128. M0-7 may separate the first half of the data between the first (DQ0-DQ2) and second nibbles (DQ3-5) of the DQ terminals. The undefined bits may separate the first half (D0-127) and the second half of the data (D128-255) between halves of the pseudo-channel (DQ0-5 and DQ6-11). M8-15 may separate the second half of the data between the third nibble (DQ6-8) and the fourth nibble (DQ9-11) of the DQ terminals. This separation of the data across the DQ terminals may further prevent errors in the data from crossing fault lines in some applications. Accordingly, the data packet definition in table 402 may provide for a bounded fault-compliant data packet definition.

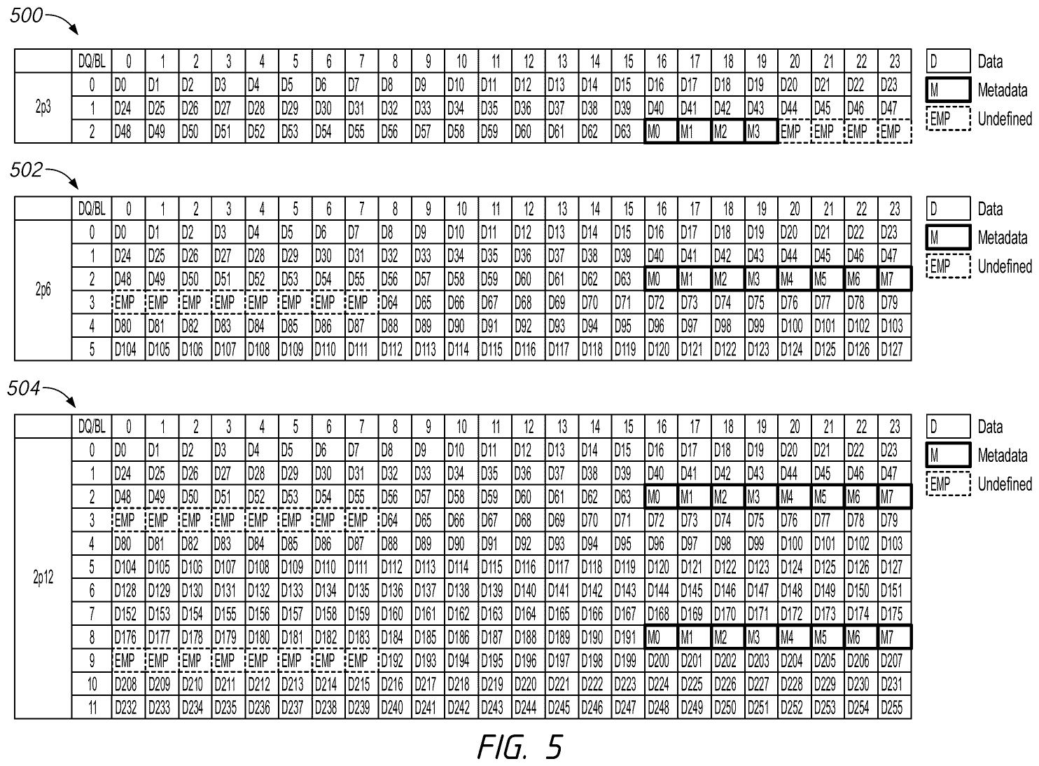

FIG. 5 illustrates data packet definitions for different architectures according to some embodiments of the present disclosure. The data packet definitions shown in FIG. 5 may be implemented by a memory device, such as one or all of memory devices 104, semiconductor device 200, and/or memory device 300 in some embodiments. The data packet definitions may also be implemented by a controller such as controller 150 and/or controller 202.

Table 500 illustrates a data packet definition for a 2p3 architecture. The data packet definition in table 500 is the same as the data packet definition of table 400. Accordingly, for reasons similar to those discussed with reference to table 400, the data packet definition shown in table 500 may provide for a bounded fault-compliant data packet definition.

Table 502 illustrates a data packet definition for a 2p6 architecture. The data packet definition for DQ0-2 are the same as the data packet definition shown in table 402. However, DQ3-5 are different. For DQ3, bits BL0-7 of a burst are undefined, and BL8-23 are D64-79. DQ4 receives D80-103 and DQ5 receives D104-127. Thus, the data packet definition in table 502 provides a same number of data bits (128), metadata bits (8), and undefined bits (8) as the data packet definition in table 402. Further, the undefined bits may be used as additional metadata bits or CRC bits as previously discussed with referent to table 402.

The data packet definition in 502 provides both the metadata bits and the undefined bits of the burst symmetrically in the data packet between D0-63 and D64-127. In some embodiments, this may create greater separation of the data between the upper and lower nibbles. Further, for the additional reasons similar to those discussed with reference to table 402, the data packet definition shown in table 502 may provide for a bounded fault-compliant data packet definition. Additionally, in some embodiments, when the undefined bits are used for metadata, providing all of the metadata bits adjacent to one another (while still on separate nibbles of the DQs) may be advantageous for retrieving and storing the metadata in the memory device and/or module depending on the arrangement of the data and metadata therein. In some embodiments, the undefined bits may be used for CRC bits.

Table 504 illustrates a data packet definition for a 2p12 architecture. The data packet definition shown in table 504 has been changed compared to table 404 in a similar manner to table 502. A first byte of undefined bits is located on DQ3 at BL0-7 instead of on DQ5 at BL16-23. A second byte of undefined bits is located on DQ9 at BL0-7 instead of on DQ11 at BL16-23. Thus, in contrast to table 404, the metadata and undefined bits are both provided symmetrically between portions of the data. M0-7 and the first byte of undefined bits are between D0-63 and D64-127, and M8-15 and the second byte of undefined bits are between D128-191 and D129-255. Further, for the additional reasons discussed with reference to table 404, the data packet definition shown in table 504 may provide for a bounded fault-compliant data packet definition. Similar to table 502, the placement of the metadata and undefined bits shown in table 504 may provide greater separation of the data between the nibbles of the DQ terminals. Further, providing the metadata and undefined bits together in the data packet may provide advantages for retrieving and storing metadata in the memory device and/or module depending on the arrangement of the data and metadata therein.

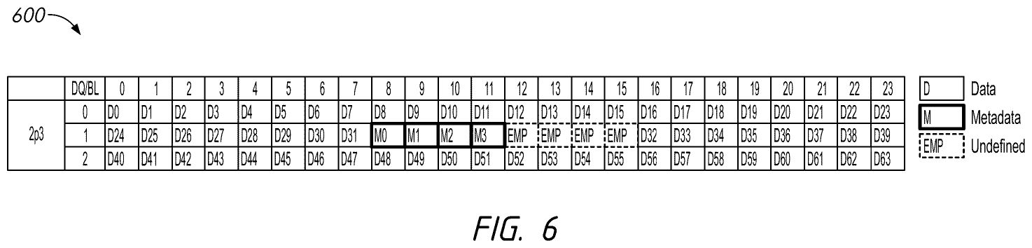

FIG. 6 illustrates a data packet definition for a 2p3 architecture according to some embodiments of the present disclosure. The data packet definition shown in FIG. 6 may be implemented by a memory device, such as one or all of memory devices 104, semiconductor device 200, and/or memory device 300 in some embodiments. The data packet definition may also be implemented by a controller such as controller 150 and/or controller 202.

Table 600 illustrates a data packet definition for a 2p3 architecture. The data packet defined in table 600 has a burst length of 24 bits (0-23). DQ0 receives data D0-23. DQ1 receives data D24-31 for BL0-7, and then receives metadata M0-3 for BL8-11, undefined bits for BL12-15, and data D32-39 for BL16-23. DQ2 receives data D40-63. The data packet includes 64 bits of data, similar to the data packets shown in table 400 and table 500. Similar to the data packet in table 500, when the bits for BL12-15 on DQ1 are undefined, there are only four metadata bits, so the pseudo-channel may provide 68 bits (64 data bits+8 metadata bits), and the undefined bits may or may not be provided. When the undefined bits are used to provide additional metadata, the pseudo-channel may provide 72 bits (64 data bits+8 metadata bits), similar to the data packet shown in table 400. In some embodiments, the undefined bits may be used for CRC bits.

In contrast to the data packets shown in tables 400 and 500, the metadata and undefined bits are placed symmetrically in the data packet between halves of the data. The metadata and undefined bits are provided between D0-31 and D32-63. Depending on how the data is stored in the memory device and/or module, the separation may provide greater segregation of faults in the data. For this reason and for similar reasons discussed with reference to tables 400 and 500, this may provide for a bounded fault-compliant data packet definition. Further, depending on the arrangement of the memory device and/or module, providing the metadata and undefined bits together as sequential bits may provide advantages for retrieving and/or storing the metadata when the undefined bits are utilized for additional metadata.

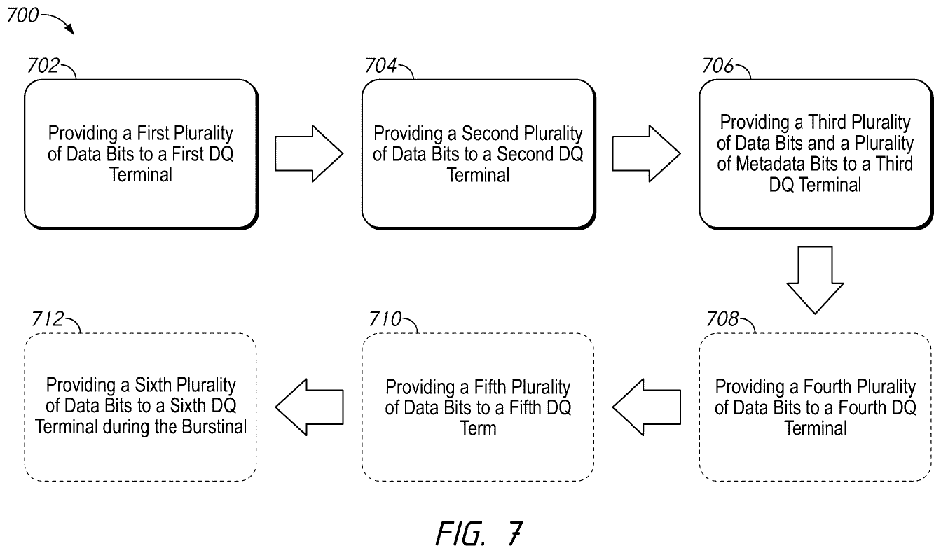

FIG. 7 is a flow chart of a method according to some embodiments of the present disclosure. The method shown in flow chart 700 may be implemented in whole or in part by a memory device, such as one or all of memory devices 104, semiconductor device 200, and/or memory device 300 in some embodiments.

At block 702, “providing a first plurality of data bits to a first DQ terminal” may be performed. At block 704, “providing a second plurality of data bits to a second DQ terminal” may be performed. At block 706, “providing a third plurality of data bits and a plurality of metadata bits to a third DQ terminal.” In some embodiments, blocks 702, 704, and/or 706 may be performed concurrently or substantially concurrently.

The data bits may be provided by a memory device, such as one disclosed herein during a burst (e.g., data burst). In some embodiments, blocks 702, 704, and/or 706 may be performed by a memory device or module having a 2p3 architecture, a 2p6 architecture, or a 2p12 architecture. In some embodiments, the DQ terminals may be the DQ terminals of a memory device. In some embodiments, the DQ terminals may be the DQ terminals of a memory module. In some embodiments, a length of the burst may be twenty-four bits. In some embodiments, a number of bits in the third plurality of data bits is less than a number of bits in the first plurality of data bits and a number of bits in the second plurality of data bits. In some embodiments, a number of the plurality of metadata bits is eight and a total number of data bits is 64 (the total number of data bits in the first, second, and third plurality of data bits is 64). In some embodiments, the plurality of metadata bits are provided before at least some data bits of the third plurality of data bits during the burst. For example, as shown in table 600. In some embodiments, the plurality of metadata bits are provided after the data bits of the third plurality of data bits during the burst. For example, as shown in tables 400, 402, 404, 500, 502, and 504.

Optionally the method shown in flow chart 700 may further include blocks 708, 710, and 712. At block 708, “providing a fourth plurality of data bits to a fourth DQ terminal” is performed. At block 710, “providing a fifth plurality of data bits to a fifth DQ terminal” is performed. At block 712, “providing a sixth plurality of data bits to a sixth DQ terminal during the burst” may be performed. In some embodiments, the information is provided by a same memory device during the burst. In some embodiments, blocks 708, 710, and/or 712 may be performed by a memory device having a 2p3 (e.g., two pseudo-channels), 2p6 (e.g., a pseudo-channel), or a 2p12 architecture (e.g., a portion of a pseudo-channel). In some embodiments, blocks 708, 710, and/or 712 may be performed concurrently or substantially concurrently. In some embodiments, blocks 708, 710, and/or 712 may be performed concurrently or substantially concurrently with blocks 702, 704, and/or 706. In some embodiments, a number of the plurality of metadata bits is eight and a total number of data bits is 128.

Optionally, the method shown in flow chart 700 further includes providing a plurality of undefined bits to the sixth DQ terminal during the burst. In some embodiments, the number of undefined bits is eight. In other embodiments, the number of undefined bits is less, such as four bits as shown in table 500 and table 600. In some embodiments, the plurality of undefined bits are provided after the sixth plurality of data bits during the burst. For example, as shown in table 402 and 404. In other embodiments, the method shown in flow chart 700 may include providing a plurality of undefined bits to the fourth DQ terminal during the burst. In some embodiments, the plurality of undefined bits are provided before the fourth plurality of data bits during the burst. For example, as shown in tables 502 and 504.

While flow chart 700 illustrates a method performed, at least in part, by a memory device, a complementary method may be implemented in whole or in part by a controller such as controller 150 and/or controller 202 in some embodiments. Data bits, metadata bits, and/or undefined bits may be provided from a controller to a memory device based on a data packet definition as disclosed herein.

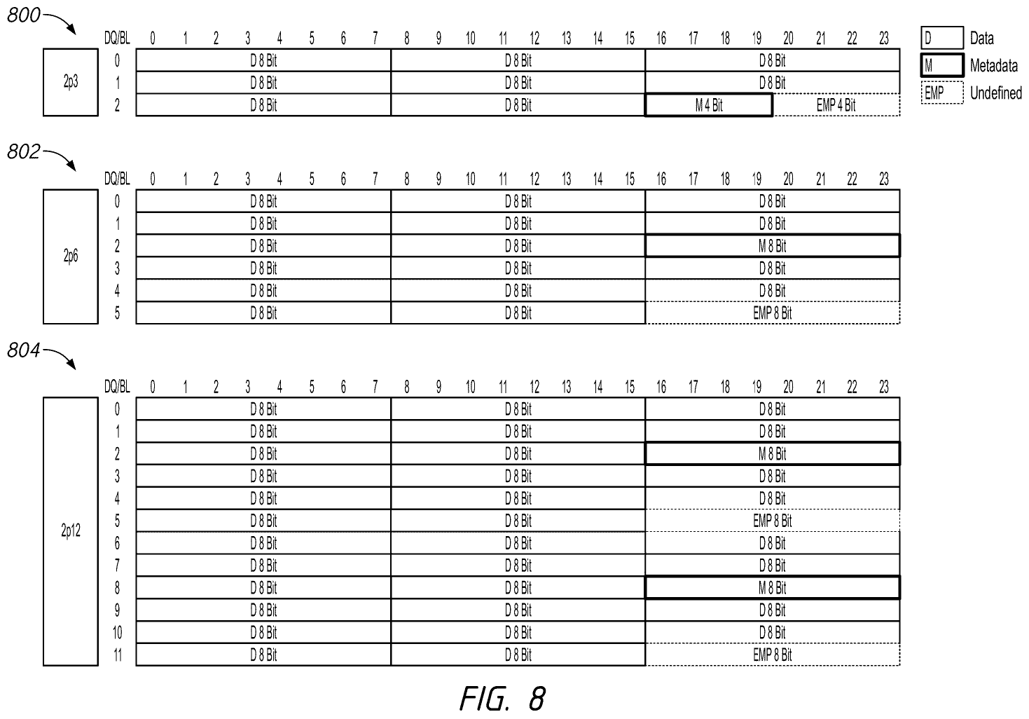

FIG. 8 illustrates data packet definitions for different architectures according to some embodiments of the present disclosure. The data packet definitions shown in FIG. 8 may be implemented by a memory device, such as one or all of memory devices 104, semiconductor device 200, and/or memory device 300 in some embodiments. The data packet definitions may also be implemented by a controller such as controller 150 and/or controller 202. The first column indicates a DQ terminal, and the top row indicates a bit in a series of bits in a burst length (BL). Further, D#indicate bits of data, M#indicate bits of metadata, and EMP indicates undefined bits. In some applications, EMP bits may not be provided, ignored, or discarded. In some applications, EMP bits may be additional bits of information for an application-specific purpose. For example, in some embodiments, the EMP bits may be used as cyclical redundancy check (CRC) bits. In some applications, EMP bits may be additional metadata bits. When the EMP bits are used as additional metadata bits, they may be stored in a different location of a memory device and/or memory module than the defined metadata bits (e.g., different column plane, different bank, etc.) in some embodiments.

In contrast to the data packet definitions shown in FIGS. 4-6, the data packet definitions in FIG. 8 illustrate how the data packet is divided into subpackets. In the example embodiment shown, the data packet is divided into subpackets. Subpackets may be utilized by system-level error correction devices, such as error correction device 110, for error correction operations. For example, an error correction device may generate parity bits or other error correction information on a subpacket basis.

Table 800 illustrates a data packet definition for a 2p3 architecture where a channel (e.g., channel 120) is divided into two pseudo-channels that each include three DQ terminals (e.g., DQ 124). In the 2p3 architecture, in some embodiments, one pseudo-channel may provide one nibble and the other pseudo-channel may provide another nibble. In some embodiments, information provided on both pseudo-channels may be provided by a same memory device. In other embodiments, information may be provided from different memory devices. Because each pseudo-channel (e.g., pseudo-channels 122) may operate independently, the data packet definition for only one pseudo-channel is shown in table 800. The data packet defined in table 800 has a burst length of 24 bits (0-23). DQ0 and DQ1 receive three 8-bit data (D) subpackets. DQ2 receives two 8-bit data subpackets for BL0-15, and third 8-bit subpacket including four bits of metadata (M) and four undefined bits (EMP) for BL16-23. In some embodiments, the undefined bits may be used for additional metadata bits, CRC bits, or another purpose.

Each DQ0-2 in table 800 has three subpackets, and no subpackets extend across different DQ (e.g., the subpackets are DQ aligned). Keeping each subpacket associated with a single DQ may reduce the risk of an error in a subpacket extending across multiple DQ. This may provide bounded fault-compliance between the subpackets and the DQs.

In some embodiments, the data packet definition shown in table 400 of FIG. 4 and/or table 500 of FIG. 5 may be utilized with the subpacket definitions shown in table 500. Variations of table 800 may be used in other embodiments. For example, the subpacket including the metadata and undefined bits may be included along DQ1 in BL8-15, similar to the data packet definition shown in table 600.

Table 802 illustrates a data packet definition for a 2p6 architecture where a channel is divided into two pseudo-channels that each include six DQ terminals. In some embodiments, information provided on both pseudo-channels may be provided by a same memory device. In other embodiments, information may be provided from different memory devices. Because each pseudo-channel may operate independently, the data packet definition for only one pseudo-channel is shown in table 802. The data packet defined in table 802 has a burst length of 24 bits (0-23). DQ0, DQ1, DQ3, and DQ4 receive three 8-bit data (D) subpackets. DQ2 receives two 8-bit data subpackets for BL0-15, and third 8-bit subpacket including eight bits of metadata (M) for BL16-23. DQ5 receives two 8-bit data subpackets for BL0-15, and third 8-bit subpacket including eight undefined bits (EMP) for BL16-23. In some embodiments, the undefined bits may be used for additional metadata bits, CRC bits, or another purpose.

Similar to the data packet definition in table 800, each DQ0-5 in table 802 has three subpackets, and no subpackets extend across different DQ and thus are DQ aligned. Keeping each subpacket associated with a single DQ may reduce the risk of an error in a subpacket extending across multiple DQ. This may provide bounded fault-compliance between the subpackets and the DQs.

In some embodiments, the data packet definition shown in table 402 of FIG. 4 may be utilized with the subpacket definitions shown in table 802. Variations of table 802 may be used in other embodiments. For example, the subpacket including the undefined bits may be included along DQ3 in BL0-7, similar to the data packet definition shown in table 502.

Table 804 illustrates a data packet definition for a 2p12 architecture where a channel is divided into two pseudo-channels that each include twelve DQ terminals. In some embodiments, information provided on both pseudo-channels may be provided by a same memory device. In other embodiments, information may be provided from different memory devices. Because each pseudo-channel may operate independently, the data packet definition for only one pseudo-channel is shown in table 404. The data packet defined in table 404 has a burst length of 24 bits (0-23). DQ0, DQ1, DQ3, DQ4, DQ6, DQ7, DQ9, and DQ10 receive three eight-bit data (D) subpackets. DQ2 and DQ8 receive two 8-bit data subpackets for BL0-15, and third 8-bit subpacket including eight bits of metadata (M) for BL16-23. DQ5 and DQ11 receive two 8-bit data subpackets for BL0-15, and third 8-bit subpacket including eight undefined bits (EMP) for BL16-23.

As with the data packet definitions in table 800 and table 802, each DQ0-11 in table 804 has three subpackets, and no subpackets extend across different DQ and thus are DQ aligned. Keeping each subpacket associated with a single DQ may reduce the risk of an error in a subpacket extending across multiple DQ. This may provide bounded fault-compliance between the subpackets and the DQs.

In some embodiments, the data packet definition shown in table 404 of FIG. 4 may be utilized with the subpacket definitions shown in table 804. Variations of table 804 may be used in other embodiments. For example, the subpackets including the undefined bits may be included along DQ3 and DQ9 in BL0-7, similar to the data packet definition shown in table 504.

In some embodiments, such as the one shown in FIG. 8, all of the subpackets include only data or only metadata (or only metadata and undefined bits). None of the subpackets include both data and metadata, nor do any subpackets include both data and undefined bits. In some embodiments, this may prevent errors in different types of data from smearing between subpackets in some applications.

Data packet as disclosed herein may allow data and/or metadata stored in a portion of a memory array to be mapped to DQ terminals such that the data and/or metadata provided is bounded fault-compliant from the perspective of an external error correction device. This may reduce or eliminate errors that are uncorrectable by the error correction device. While the examples provided herein describe the IO circuit (e.g., IO circuit 260, IO circuit 334) as implementing the data packet definition by organizing the bits transmitted to and from the memory device, in other examples, other components and/or additional components may organize the bits to implement the data packet definitions.

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a plurality of channels, individual ones of the plurality of channels comprising a plurality of data (DQ) terminals organized into a plurality of nibbles; and
a plurality of memory devices coupled to corresponding ones of the plurality of channels, wherein at least one of the plurality of memory devices is configured to transmit, receive a plurality of data bits and a plurality of metadata bits to or from the DQ terminals as a data packet,
wherein a first portion of the plurality of data bits is provided to a first nibble of the plurality of nibbles and a second portion of the plurality of data bits is provided to a second nibble of the plurality of nibbles, and
wherein the metadata is provided in the data packet between the first portion and the second portion of the plurality of data bits.

2. The apparatus of claim 1, wherein the plurality of metadata bits is provided to the first nibble.

3. The apparatus of claim 1, wherein the plurality of metadata bits is provided to one DQ terminal of the plurality of DQ terminals.

4. The apparatus of claim 1, wherein the data packet further comprises a plurality of undefined bits.

5. The apparatus of claim 4, wherein the plurality of metadata bits is provided to the first nibble and the plurality of undefined bits are provided to the second nibble.

6. The apparatus of claim 4, wherein the plurality of metadata bits and the plurality of undefined bits are provided to a same DQ terminal of the plurality of DQ terminals.

7. The apparatus of claim 4, wherein the plurality of metadata bits is provided to a first DQ terminal of the plurality of DQ terminals and the plurality of undefined bits is provided to a second DQ terminal of the plurality of DQ terminals.

8. The apparatus of claim 4, wherein the plurality of undefined bits may be used as additional metadata bits.

9. The apparatus of claim 4, wherein the plurality of metadata bits and the plurality of undefined bits are provided in the data packet between the first portion and the second portion of the plurality of data bits.

10. The apparatus of claim 1, further comprising an error correction device configured to store error correction information for the plurality of data bits, the plurality of metadata bits, or a combination thereof.

11. The apparatus of claim 1, further comprising module logic configured to receive commands, addresses, and clock signals from a controller and distribute the commands, addresses, and clock signals to the plurality of memory devices.

12. The apparatus of claim 1, wherein the data packet is organized into a plurality of subpackets, and individual subpackets of the plurality of subpackets are provided to individual ones of the plurality of DQ terminals.

13. The apparatus of claim 12, wherein the individual ones of the plurality of DQ terminals receives three subpackets of the plurality of subpackets.

14. The apparatus of claim 12, wherein individual subpackets of the plurality of subpackets include data or metadata, but not both.

15. A memory device comprising:
a memory array configured to store a plurality of data bits and a plurality of metadata bits; and
an input/output (IO) circuit configured to arrange the plurality of data bits and the plurality of metadata bits into a data packet,
wherein a first portion of the plurality of data bits are provided in a first portion of the data packet and a second portion of the plurality of data bits are provided in a second portion of the data packet, and the plurality of metadata bits are provided between the first portion and the second portion of the plurality of data bits.

16. The memory device of claim 15, further comprising a plurality of data (DQ) terminals configured to receive the plurality of data bits and the plurality of metadata bits from the IO circuit or transmit the plurality of data bits and the plurality of metadata bits to the IO circuit.

17. The memory device of claim 16, wherein the plurality of metadata bits are provided one DQ terminal of the plurality of DQ terminals.

18. The memory device of claim 16, wherein the plurality of data bits are stored in a plurality of column planes and data bits of the plurality of data bits stored in a column plane of the plurality of column planes are transmitted or received on one DQ terminal of the plurality of DQ terminals.

19. The memory device of claim 16, wherein the plurality of DQ terminals are organized into an upper nibble and a lower nibble, wherein the first portion of the data packet is provided to the lower nibble and the second portion of the data packet is provided to the lower nibble.

20. The memory device of claim 19, wherein three DQ terminals are included in the upper nibble and three DQ terminals are included in the lower nibble.

21. The memory device of claim 15, wherein a third portion of the plurality of data bits are provided to a third portion of the data packet and a fourth portion of the plurality of data bits are provided to a fourth portion of the data packet.

22. The memory device of claim 21, wherein a second plurality of metadata bits are provided between the third portion and the fourth portion of the plurality of data bits.

23. The memory device of claim 22, wherein the second plurality of metadata bits are stored in a different portion of the memory array than the plurality of metadata bits.

24. The memory device of claim 21, wherein a first plurality of undefined bits are provided in the second portion of the data packet.

25. The memory device of claim 24, wherein the first plurality of undefined bits are provided before the second portion of the plurality of data bits in the second portion of the data packet.

26. The memory device of claim 24, wherein the first plurality of undefined bits are provided after the second portion of the plurality of data bits in the second portion of the data packet.

27. The memory device of claim 24, wherein a second plurality of undefined bits are provided in the fourth portion of the data packet.

28. A method comprising:
providing, from a memory device, a first plurality of data bits to a first data (DQ) terminal during a burst;
providing, from the memory device, a second plurality of data bits to a second DQ terminal during the burst; and
providing, from the memory device, a third plurality of data bits and a plurality of metadata bits to a third DQ terminal during the burst.

29. The method of claim 28, wherein a length of the burst is twenty-four bits.

30. The method of claim 28, wherein a number of bits in the third plurality of data bits is less than a number of bits in the first plurality of data bits and a number of bits in the second plurality of data bits.

31. The method of claim 28, wherein the plurality of metadata bits are provided before at least some data bits of the third plurality of data bits during the burst.

32. The method of claim 28, further comprising:
providing, from the memory device, a fourth plurality of data bits to a fourth DQ terminal during the burst;
providing, from the memory device, a fifth plurality of data bits to a fifth DQ terminal during the burst; and
providing, from the memory device, a sixth plurality of data bits to a sixth DQ terminal during the burst.

33. The method of claim 32, further comprising providing a plurality of undefined bits to the sixth DQ terminal during the burst.

34. The method of claim 33, wherein the plurality of undefined bits are provided after the sixth plurality of data bits during the burst.

35. The method of claim 32, further comprising providing a plurality of undefined bits to the fourth DQ terminal during the burst.

36. The method of claim 35, wherein the plurality of undefined bits are provided before the fourth plurality of data bits during the burst.

37. The method of claim 32, wherein a number of the plurality of metadata bits is eight and a total number of data bits is 128.

38. The method of claim 28, wherein a number of the plurality of metadata bits is four and a total number of data bits is 64.
